(19) United States
(12) Patent Application Publication
(10) Pub. No.: US 2026/0006996 A1
(43) Pub. Date: Jan. 1, 2026

(54) DISPLAY SUBSTRATE AND PREPARATION METHOD THEREFOR, AND DISPLAY PANEL

(71) Applicant: BOE Technology Group Co., Ltd., Beijing (CN)

(72) Inventor: Dejiang ZHAO, Beijing (CN)

(73) Assignee: BOE Technology Group Co., Ltd., Beijing (CN)

(21) Appl. No.: 18/995,863

(22) PCT Filed: Aug. 22, 2023
(86) PCT No.: PCT/CN2023/114195

§ 371 Date: Jan. 17, 2025

(30) Foreign Application Priority Data
Sep. 22, 2022 (CN) 202211115722.2

(51) Int. Cl. H10K 59/122; H10K 59/12

(52) U.S. Cl. CPC H10K 59/122; H10K 59/1201

(57) ABSTRACT

A display substrate includes: a base substrate; a plurality of first barrier structures arranged in an array on a side of the base substrate, each of the first barrier structures enclosing a first region; and a first electrode layer comprising a plurality of first electrodes, the plurality of first electrodes being arranged corresponding to the plurality of first barrier structures, and each of the first electrodes being within the first region enclosed by the corresponding first barrier structure, wherein each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate.

### CROSS-REFERENCE TO RELATED APPLICATIONS

This disclosure is the U.S. national phase application of PCT Application No. PCT/CN2023/114195, filed on Aug. 22, 2023, which claims priority to Chinese Patent Application No. 202211115722.2, filed on Sep. 14, 2022 and entitled “Display Substrate and Preparation Method Therefor, and Display Panel”. The entire content of foregoing applications is incorporated herein by reference in their entireties.

### TECHNICAL FIELD

This disclosure relates to the field of display technology, in particular to a display substrate and a preparation method therefor, as well as a display panel.

### BACKGROUND

OLED (Organic Light-Emitting Diode) is different from traditional LCD products in that it does not need to be driven by an external backlight, and its basic light-emitting principle is that current flows through EL light-emitting materials to produce electroluminescence. Therefore, OLED display devices have advantages of being light, thin and having a broad viewing angle.

In the related art, it is a challenging issue in the industry to realize ultra-high ppi production by using a solution method. On the one hand, the smaller the ink droplets are, the more precise the equipment for ejecting the ink droplets needs to be, and uniformity of the ink droplets is difficult to control. Meanwhile, as the ink droplets become small, a ratio of a volume to a surface area of the ink droplets has changed greatly, and a drying effect of the ink is significantly enhanced, making it difficult to control film-forming morphology after the ink dries.

It should be noted that information disclosed in the Background is only used to acquire a better understanding of the background of this disclosure and therefore may include information that does not constitute the prior art already known to those skilled in the art.

### SUMMARY

An object of this disclosure is to overcome shortcomings in the related art by providing a display substrate, a preparation method therefor, and a display panel.

According to one aspect of this disclosure, there is provided a display substrate, including: a base substrate; a plurality of first barrier structures arranged in an array on a side of the base substrate, each of the first barrier structures enclosing a first region; and a first electrode layer including a plurality of first electrodes, the plurality of first electrodes being arranged corresponding to the plurality of first barrier structures, and each of the first electrodes being within the first region enclosed by the corresponding first barrier structure. Each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate.

In an exemplary embodiment of this disclosure, a ratio of a recessing depth of the separation groove in the thickness direction of the base substrate to the first height is greater than or equal to 0.2 and less than or equal to 0.4.

In an exemplary embodiment of this disclosure, an orthographic projection of the side surface of each of the first barrier structures, on which the separation groove is formed, on the base substrate has a first width; an orthographic projection of an opening of the separation groove on the base substrate has a second width; and a ratio of the second width to the first width is greater than or equal to 0.2 and less than or equal to 0.6.

In an exemplary embodiment of this disclosure, the ratio of the second height to the first height is greater than or equal to 0.4 and less than or equal to 0.7.

In an exemplary embodiment of this disclosure, the display substrate further includes: a plurality of second barrier structures arranged in an array on the base substrate and corresponding to the plurality of first barrier structures, each of the second barrier structures enclosing a second region. Each of the first barrier structures is within the second region enclosed by the corresponding second barrier structure, and there is a gap between the first barrier structure and the corresponding second barrier structure. Each of the second barrier structures has a third height in the thickness direction of the base substrate, and the third height is greater than the first height.

In an exemplary embodiment of this disclosure, a ratio of the first height to the third height is greater than or equal to 0.4 and less than or equal to 0.8.

In an exemplary embodiment of this disclosure, a distance between centers of orthographic projections of any adjacent two of the second barrier structures on the base substrate is D. An orthographic projection of each of the first barrier structures on the base substrate has a first side edge and a second side edge opposite to each other; any normal line of the first side edge intersects with the first side edge at a first node and intersects with the second side edge at a second node; and a distance between the first node and the second node is d1. An orthographic projection of each of the second barrier structures on the base substrate has a third side edge and a fourth side edge opposite to each other; any normal line of the third side edge intersects with the third side edge at a third node and intersects with the fourth side edge at a fourth node; and a distance between the third node and the fourth node is d2, in which d1/D is 0.1-0.3 and d2/D is 0.1-0.3.

In an exemplary embodiment of this disclosure, the second side edge is on a side of the first side edge away from an orthographic projection of the corresponding first electrode on the base substrate, and the fourth side edge is on a side of the third side edge away from an orthographic projection of the corresponding first electrode on the base substrate; any normal line of the second side edge intersects with the second side edge at a fifth node and intersects with the third side edge at a sixth node, and a distance between the fifth node and the sixth node is d3, in which d3/D is 0.08-0.20.

In an exemplary embodiment of this disclosure, the second barrier structure includes a first structural layer and a second structural layer parallel to the base substrate, the first structural layer is located at any position on a side of the second structural layer away from the base substrate, and an orthographic projection of the first structural layer on the base substrate is within an orthographic projection of the second structural layer on the base substrate; the first barrier structure includes a third structural layer and a fourth structural layer parallel to the base substrate, the third structural layer is located at any position of the fourth structural layer away from the base substrate, and an orthographic projection of the third structural layer on the base substrate is within an orthographic projection of the fourth structural layer on the base substrate.

In an exemplary embodiment of this disclosure, the first structural layer only has a first intersection point with a first tangent plane perpendicular to the base substrate; the second structural layer only has a second intersection point with a second tangent plane perpendicular to the base substrate; the first tangent plane is parallel to the second tangent plane, and the first tangent plane and the second tangent plane are located on a same side of a center of the orthographic projection of the first structural layer on the base substrate; a line segment connecting the first intersection point and the second intersection point forms a first angle with the base substrate, and the first angle is greater than or equal to 20° and less than or equal to 60°.

In an exemplary embodiment of this disclosure, the display substrate further includes: a plurality of auxiliary electrodes arranged corresponding to the plurality of second barrier structures, wherein the auxiliary electrodes correspondingly cover the second barrier structures.

In an exemplary embodiment of this disclosure, a thickness of each of the auxiliary electrodes is 3000 Å to 5000 Å.

In an exemplary embodiment of this disclosure, the second barrier structures are made of a resin material, and the resin material has a viscosity of 20 cps to 40 cps.

In an exemplary embodiment of this disclosure, a distance between centers of orthographic projections of any adjacent two of the second barrier structures on the base substrate is less than or equal to 10 μm.

In an exemplary embodiment of this disclosure, the display substrate further includes: a plurality of cushion layers arranged corresponding to the plurality of first electrodes, and positioned between the first electrodes and the base substrate. Each first barrier structure and each first electrode are located on a surface of a side of the corresponding cushion layer away from the base substrate, and the first height and the second height each include a thickness of the corresponding cushion layer in the thickness direction of the base substrate; or each of the cushion layers is located within the first region formed by the corresponding first barrier structure, the second height includes the thickness of the corresponding cushion layer in the thickness direction of the base substrate, and the first height does not include the thickness of the corresponding cushion layer in the thickness direction of the base substrate.

According to a second aspect of this disclosure, there is provided a display panel, including: the display substrate according to any one of the embodiments of this disclosure; a light-emitting layer including a plurality of light-emitting structures, wherein the plurality of light-emitting structures are in one-to-one correspondence with the plurality of first electrodes, and the light-emitting structures correspondingly cover the first electrodes; and a second electrode layer covering the light-emitting layer and the plurality of first barrier structures, wherein a portion of the second electrode layer within the second barrier structure extends to the second barrier structure and is connected with the auxiliary electrode.

In an exemplary embodiment of this disclosure, the display panel further includes: a first organic layer between the first electrode layer and the light-emitting layer, wherein the first organic layer further includes first organic structures in one-to-one correspondence with the plurality of first electrodes, and the first organic structures correspondingly cover the first electrodes; and a second organic layer between the light-emitting layer and the second electrode layer, wherein the second organic layer includes second organic structures in one-to-one correspondence with the plurality of first electrodes, and the second organic structures correspondingly cover the light-emitting structures. At least one of the light-emitting layer, the first organic layer, and the second organic layer is formed by an inkjet process.

According to a third aspect of this disclosure, there is provided a preparation method for the display substrate according to any one of the embodiments of this disclosure. The preparation method includes: providing a base substrate; forming a first electrode layer on a side of the base substrate, wherein the first electrode layer includes a plurality of first electrodes; and forming a plurality of first barrier structures on the base substrate. The plurality of first barrier structures are in one-to-one correspondence with the plurality of first electrodes, and each of the first electrodes is within a first region enclosed by the corresponding first barrier structure; each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate.

According to a third aspect of this disclosure, there is provided a preparation method for the display substrate according to any one of the embodiments of this disclosure. The preparation method includes: providing a base substrate; forming a first electrode layer on a side of the base substrate, wherein the first electrode layer includes a plurality of first electrodes; forming a plurality of first barrier structures on the base substrate, in which the plurality of first barrier structures are in one-to-one correspondence with the plurality of first electrodes, and each of the first electrodes is within a first region enclosed by the corresponding first barrier structure; each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate; and forming a plurality of second barrier structures on the base substrate, in which the plurality of second barrier structures are arranged in one-to-one correspondence with the plurality of first barrier structures; each of the first barrier structures is within a second region enclosed by the corresponding second barrier structure; there is a gap between the first barrier structure and the corresponding second barrier structure; and each of the second barrier structures has a third height in the thickness direction of the base substrate, and the third height is greater than the first height.

For the display substrate provided by this disclosure, the first electrode layer includes the plurality of first electrodes, and each of the first electrodes is correspondingly arranged within the first region enclosed by one of the first barrier structures, and the height of the first barrier structure is higher than the height of the first electrode, so that ink ejected by a printing device forms a corresponding film layer on the first electrode within the first region. Each of the first barrier structures is provided with the separation groove. Excessive ink may overflow the region enclosed by the first barrier structure, and the separation groove on the first barrier structure may cut the overflowing ink droplets, to separate the overflowing ink droplets from the ink droplets on the first electrode layer. As a result, ink morphology after drying can be effectively controlled, to achieve ultra-high ppi production of the solution method and solve the problem that the morphology of the ink after being solidified is difficult to be controlled.

It shall be understood that the above general description and the following detailed description are merely exemplary and explanatory and are not intended to be restrictive of this disclosure.

### BRIEF DESCRIPTION OF THE DRAWINGS

The accompanying drawings, which are incorporated in and constitute a part of this specification, illustrate embodiments consistent with this disclosure and together with the description, serve to explain the principles of this disclosure. Apparently, the drawings in the following description are only for illustrating some embodiments of this disclosure and those skilled in the art may also derive other drawings based on the drawings without paying any creative effort.

FIG. 1 is a schematic structural view of a display substrate according to an embodiment of this disclosure;

FIG. 2 is a sectional view of one sub-pixel along A-A direction in FIG. 1;

FIG. 3 is a sectional view along the A-A direction in FIG. 1 according to another embodiment of this disclosure;

FIG. 4 is a partial enlarged view of a second barrier structure in FIG. 3;

FIG. 5 is a schematic structural view of a display panel according to an embodiment of this disclosure;

FIG. 6 is a schematic structural view of a first electrode formed according to an embodiment of this disclosure;

FIG. 7 is a structural schematic view of a first barrier structure formed according to an embodiment of this disclosure;

FIG. 8 is a structural schematic view of a second barrier structure formed according to an embodiment of this disclosure;

FIG. 9 is a schematic structural view of an auxiliary electrode formed according to an embodiment of this disclosure.

### DETAILED DESCRIPTION

Now, the exemplary embodiments will be described more fully with reference to the accompanying drawings. However, the exemplary embodiments may be embodied in a variety of forms and should not be construed as limiting the embodiments set forth herein. Instead, these embodiments are provided so that this disclosure will be thorough and complete, and the concepts of the exemplary embodiments will be fully given to those skilled in the art. Same reference numbers denote the same or similar structures in the figures, and thus the detailed description thereof will be omitted. In addition, the drawings are merely schematic illustrations of this disclosure, and are not necessarily drawn to scale.

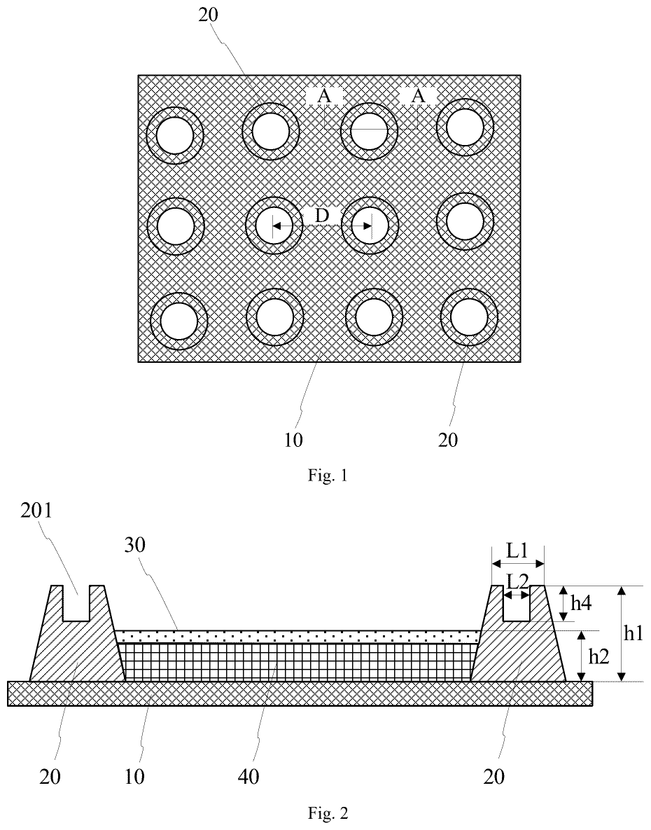

FIG. 1 is a schematic structural view of a display substrate according to an embodiment of this disclosure, and FIG. 2 is a sectional view of one sub-pixel along A-A direction in FIG. 1. As shown in FIGS. 1 and 2, the display substrate may include a base substrate 10 and a plurality of first barrier structures 20 formed on the base substrate 10 and a first electrode layer. The plurality of first barrier structures 20 are arranged in an array on a side of the base substrate 10, and each of the first barrier structures 20 encloses a first region. The first electrode layer includes a plurality of first electrodes 30 that are arranged corresponding to the first barrier structures 20. The first electrode 30 is within the first region formed by the corresponding first barrier structure 20. The first barrier structure 20 has a first height hl in a thickness direction of the base substrate 10. The first electrode 30 has a second height h2 in the thickness direction of the base substrate 10. The first height hl is greater than the second height h2. A separation groove 201 is provided on a side surface of the first barrier structure 20 away from the base substrate 10.

For the display substrate provided by this disclosure, the first electrode layer includes the plurality of first electrodes 30, and each of the first electrodes 30 is correspondingly arranged within the first region enclosed by one of the first barrier structures 20, and the height of the first barrier structure 20 is higher than the height of the first electrode 30, so that ink ejected by a printing device forms a corresponding film layer on the first electrode 30 within the first region. Each of the first barrier structures 20 is provided with the separation groove 201. Excessive ink may overflow the region enclosed by the first barrier structure 20, and the separation groove 201 on the first barrier structure may cut the overflowing ink droplets, to separate the overflowing ink droplets from the ink droplets on the first electrode layer. As a result, ink morphology after drying can be effectively controlled, to achieve ultra-high ppi production of the solution method and solve the problem that the morphology of the ink after being solidified is difficult to be controlled.

As shown in FIG. 1, in an exemplary embodiment, the first barrier structures 20 and the first electrodes 30 are all arranged in an array on the base substrate 10. The first barrier structures 20 may be in one-to-one correspondence with the first electrodes 30. The first electrode 30 is within the first region enclosed by the corresponding first barrier structure 20, in other words, the first barrier structure 20 surrounds the corresponding first electrode 30 in a circumferential direction. The first height h1 of the first barrier structure 20 in the thickness direction is greater than the second height h2 of the first electrode 30 in the thickness direction, thus forming an accommodation space for accommodating a structural layer of a sub-pixel on the first electrode 30. The ink ejected from the printing device is shaped within the accommodating space to form display sub-pixels.

It should be noted that the height of the structure in the thickness direction of the base substrate 10, as described in this disclosure, may be understood as a maximum distance from each discrete point on a surface of the structure away from the base substrate 10 to the base substrate 10 along the thickness direction of the base substrate 10.

A separation groove 201 is provided on a surface of the first barrier structure 20 away from the base substrate 10. It may be understood that the separation groove 201 surrounds the corresponding first electrode 30. After the printing device ejects ink droplets, the excessive ink may overflow the accommodation space enclosed by the first barrier structure 20. The separation groove 201 may separate the overflowing ink from effective ink in the accommodation space, thereby trimming edges of the ink through the separation groove 201, so that the effective ink forming the structure of the display sub-pixels can be effectively cut off from the overflowing excessive ink.

It can be understood that the separation groove 201 of this disclosure may have different profiles. For example, the cross-sectional structure of the separation groove 201 in the thickness direction of the base substrate 10 may be rectangular, trapezoidal, inverted trapezoidal, etc.

It can be understood that the first electrode 30 is within the first region enclosed by the first barrier structure 20, and the first electrode 30 may abut against an inner wall of the first barrier structure 20, so that there is no gap between the inner wall of the first barrier structure 20 and a contact surface of the first electrode 30 positioned therein. This allows the ink ejected by the printing device to be merely formed on the first electrode 30 so as to form a corresponding film layer.

As shown in FIG. 2, in an exemplary embodiment, a ratio of a recessing depth h4 of the separation groove 201 in the thickness direction of the base substrate 10 to the first height h1 is greater than or equal to 0.2 and less than or equal to 0.4, that is, the ratio of the depth h4 of the separation groove 201 to a height of the first barrier structure 20 is 0.2-0.4, for example, 0.2, 0.3, 0.4, etc. The above proportional relationship between the depth h4 of the separation groove 201 and the height of the first barrier structure 20 can ensure the trimming effect of the separation groove 201 on the ink edges, and separate the excessive ink from the effective ink formed on the first electrode 30.

As shown in FIG. 2, in the exemplary embodiment, an orthographic projection of a surface of the first barrier structure 20, on which the separation groove 201 is provided, on the base substrate 10 has a first width L1. An orthographic projection of an opening of the separation groove 201 on the base substrate 10 has a second width L2. A ratio of the second width L2 to the first width L1 is greater than or equal to 0.2 and less than or equal to 0.6. A ratio of the second width L2 to the first width L1 may be 0.2, 0.3, 0.4, 0.5, 0.6, etc. It may be understood that the second width L2 reflects a width of the opening of the separation groove 201; the first width L1 reflects a width of the surface of the first barrier structure 20, in which the separation groove 201 is provided; and the width of the separation groove 201 also affects the trimming effect of the separation groove 201 on the ink edge. The above proportional relationship between the second width L2 and the first width L1 can avoid the separation groove 201 from being too narrow to lose or reduce the decoration effect on the ink edge while being compatible with the fabrication process.

It should be understood that a width of an orthographic projection of a certain structure according to this disclosure on the base substrate 10 may be understood as a distance difference between two side edges of the orthographic projection of the structure on the base substrate 10 and a center of the orthographic projection of the first electrode 30 within a region enclosed by the structure on the base substrate 10.

As shown in FIG. 2, in an exemplary embodiment, a ratio of the second height h2 to the first height h1 is greater than or equal to 0.4 and less than or equal to 0.7. The ratio of the second height h2 to the first height h1 may be, for example, 0.4, 0.5, 0.6, 0.7, etc. It may be understood that a height difference between the second height h2 and the first height hl may determine a volume of the ink to be accommodated. The above proportional relationship between the second height h2 and the first height h1 can match the formed accommodation space to the volume of the ink ejected by the printing device, so that a film structure of the display sub-pixels can be formed on the first electrode 30.

Furthermore, the display substrate of this disclosure may further include a plurality of cushion layers 40. The plurality of cushion layers 40 are arranged corresponding to a plurality of first electrodes 30. For example, one cushion layer 40 may correspond to one first electrode 30. The cushion layer 40 is arranged between the first electrode 30 and the base substrate 10, that is, the cushion layer 40 is arranged on the base substrate 10 and the first electrode 30 is arranged on the cushion layer 40. In some embodiments of this disclosure, both the first barrier structures 20 and the first electrodes 30 are arranged on a surface of a side of the cushion layer 40 away from the base substrate 10. Accordingly, both the first height h1 and the second height h2 include the thickness of the cushion layer 40 in the thickness direction of the base substrate 10. In other embodiments of this disclosure, the cushion layer 40 is arranged within the first region formed by the corresponding first barrier structure 20. Accordingly, the second height h2 includes the thickness of the cushion layer 40 in the thickness direction of the base substrate 10, and the first height h1 does not include the thickness of the cushion layer 40 in the thickness direction of the base substrate 10.

In an exemplary embodiment, the display substrate of this disclosure may further include a planarization layer PLN. It is possible to form the planarization layer PLN on a side of the base substrate 10, and then form a cushion layer 40 on the planarization layer PLN and form first electrodes 30 on the cushion layer PLN.

In an exemplary embodiment, the display substrate may be used to form OLED devices. The first electrodes 30 on the display substrate may be an anode, and accordingly the above cushion layer 40 may be an anode cushion layer. The ink ejected by the printing device forms a light-emitting functional layer of the OLED device on the anode. Certainly, in other embodiments, the first electrode 30 may also be a cathode, this disclosure is not limited thereto.

FIG. 3 is a sectional view along the direction A-A in FIG. 1 according to another implementation of this disclosure. As shown in FIGS. 1 and 3, in an exemplary embodiment, the display substrate may further include a plurality of second barrier structures 50. The plurality of second barrier structures 50 are arranged in an array on the base substrate 10 and are arranged corresponding to the plurality of first barrier structures 20. The second barrier structure 50 encloses a second region. The first barrier structure 20 is within the second region enclosed by the corresponding second barrier structure 50. There is a gap 60 between the first barrier structure 20 and the corresponding second barrier structure 50. The second barrier structure 50 has a third height h3 in the thickness direction of the base substrate 10, and the third height h3 is higher than the first height h1.

The second barrier structures 50 are arranged corresponding to the first barrier structures 20; for example, one second barrier structure 50 corresponds to one first barrier structure 20, that is, the second barrier structures 50 are in one-to-one correspondence with the first barrier structures 20. Certainly, in other embodiments, the corresponding configuration may also have other corresponding relationships.

The first barrier structure 20 is within the second region enclosed by the corresponding second barrier structure 50, in other words, the second barrier structure 50 circumferentially surrounds the first barrier structure 20, thus forming a barrier region in a circumferential direction of the first barrier structure 20. As above described, the first region enclosed by the first barrier structure 20 is used to form one display sub-pixel. The second barrier structure 50 may be arranged on a periphery of the first barrier structure 20. The display sub-pixel may be isolated from the adjacent display sub-pixel by the second barrier structure 50. Specifically, the gap 60 between the second barrier structure 50 and the first barrier structure 20 forms a trench. A part of the ink ejected by the printing device in the first region enclosed by the first barrier structure 20 is used to form a corresponding film layer of the display sub-pixel. The ink overflowing from the first barrier structure 20 may flow into the trench and be confined within the trench by the second barrier structure 50, thereby avoiding crosstalk between the overflowing excessive ink and other sub-pixels.

The third height h3 of the second barrier structure 50 in the thickness direction of the base substrate 10 is greater than the first height h1 of the first barrier structure 20 in the thickness direction of the base substrate 10. In an exemplary embodiment, a ratio of the first height h1 to the third height h3 may be greater than or equal to 0.4 and less than or equal to 0.8 and, for example, may be 0.4, 0.5, 0.6, 0.7, 0.8, etc. Due to the above proportional relationship between the height of the first barrier structure 20 and the height of the second barrier structure 50, on the one hand, the height of the second barrier structure 50 may be higher than the height of the formed display sub-pixel to form an isolation effect on the display sub-pixel; on the other hand, a slope of the second barrier structure 50 can be slowed down by limiting the height of the second barrier structure 50, so that the auxiliary electrode and the second electrode formed on the second barrier structure 50 can be prevented from being broken.

Furthermore, the material forming the second barrier structure 50 needs to have a certain viscosity, so that the formed second barrier structure 50 may meet the height requirements. For example, the viscosity of the material forming the second barrier structure 50 may be 20 cps to 40 cps, so that the height of the formed second barrier structure 50 may be 2 to 2 μm to 2.5 μm. The material of the second barrier structure 50 may be, for example, a resin material. The resin material is an acrylic system with high viscosity. Certainly, in other embodiments, the second barrier structure 50 may also be made of other materials.

As shown in FIGS. 1 and 3, in the exemplary embodiment, a distance between centers of orthographic projections of any adjacent two of the second barrier structures 50 on the base substrate 10 is D; an orthographic projection of each of the first barrier structures 20 on the base substrate 10 has a first side edge and a second side edge opposite to each other, and any normal line of the first side edge intersects with the first side edge at a first node and intersects with the second side edge at a second node, and a distance between the first node and the second node is d1; an orthographic projection of each of the second barrier structures 50 on the base substrate 10 has a third side edge and a fourth side edge opposite to each other, and any normal line of the third side edge intersects with the third side edge at a third node and intersects with the fourth side edge at a fourth node, and a distance between the third node and the fourth node is d2; wherein d1/D is 0.1-0.3 and d2/D is 0.1-0.3 and, for example, may be 0.1, 0.15, 0.2, 0.25, 0.3, etc. The distance D reflects a width of the display sub-pixel, and the distance dl between the first node and the second node represents a width of the first barrier structure 20. By setting the width of the first barrier structure 20 and the width of the sub-pixel to have the above proportional relationship, the structural stability of the first barrier structures 20 can be significantly enhanced in the implementation of ultra-high ppi pixel structures, preventing the first barrier structures from being too narrow to be broken. Similarly, the distance d2 between the third node and the fourth node represents the width of the second barrier structure 50. By setting the width of the second barrier structure 50 and the width of the sub-pixel to have the above-mentioned proportional relationship, the structural stability of the second barrier structures 50 can be significantly enhanced in the implementation of ultra-high ppi pixel structures, preventing the second barrier structures from being broken. For example, in an embodiment, a distance D between the centers of the orthographic projections of any adjacent two of the second barrier structures 50 on the base substrate 10 is less than or equal to 10 μm, and accordingly, the width of the first barrier structure 20 and the width of the second barrier structure 50 may be 1 μm to 2 μm, thereby forming the ultra-high ppi pixel structures.

Furthermore, a ratio of the distance d1 to the distance d2 may be 0.8-1.2 and, for example, may be 0.8, 0.9, 1.0, 1.1, 1.2, etc. That is, the width of the first barrier structure 20 may be slightly larger than that of the second barrier structure 50, or may be the same as or slightly smaller than that of the second barrier structure 50.

As shown in FIG. 3, in the exemplary embodiment, the second side edge is located on a side of the first side edge away from the orthographic projection of the corresponding first electrode 30 on the base substrate 10, and the fourth side edge is located on a side of the third side edge away from the orthographic projection of the corresponding first electrode 30 on the base substrate 10, that is, the second side edge is the orthographic projection formed by an outer side edge of the first barrier structure 20, the first side edge is the orthographic projection formed by an inner side edge of the first barrier structure 20, and the fourth side edge is the orthographic projection formed by an outer side edge of the second barrier structure 50, and the third side edge is the orthographic projection formed by an inner side edge of the second barrier structure 50. Any normal line of the second side edge intersects with the second side edge at the fifth node and intersects with the third side edge at the sixth node. A distance between the fifth node and the sixth node is d3, and d3/D may be 0.08-0.20 and, for example, may be 0.08, 0.10, 0.14, 0.18, 0.20, etc. The distance between the fifth node and the sixth node reflects a width of the gap 60 between the first barrier structure 20 and the second barrier structure 50. It may be understood that the width of the gap 60 determines the accommodation space of the trench. Due to the above proportional relationship between the width of the gap 60 and the width of the pixel, a space that can accommodate more ink and occupy less pixel space is provided, which is conducive to achieve a high ppi pixel structure.

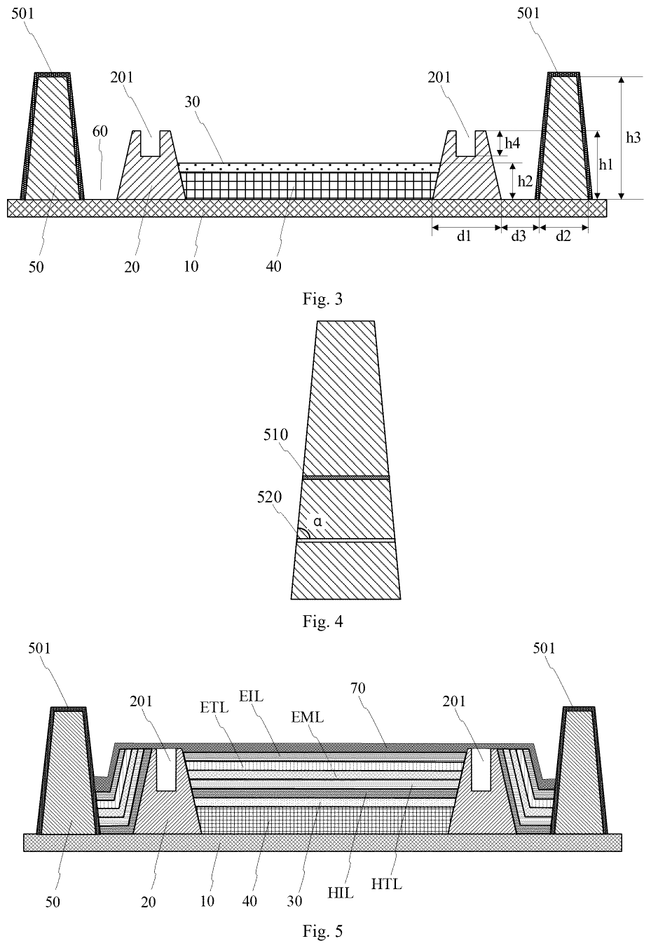

It may be understood that both the first barrier structures 20 and the second barrier structures 50 of this disclosure may have different profiles. FIG. 4 is a partial enlarged view of the second barrier structure in FIG. 3. As shown in FIG. 4, in an exemplary embodiment, the second barrier structure 50 may include a first structural layer 510 and a second structural layer 520 parallel to the base substrate 10. The first structural layer 510 is located at any position on the side of the second structural layer 520 away from the base substrate 10. An orthographic projection of the first structural layer 510 on the base substrate 10 is within an orthographic projection of the second structural layer 520 on the base substrate 10. The first structural layer 510 and the second structural layer 520 may be understood as cross-sectional structures of the second barrier structure 50 on the plane parallel to the base substrate 10. The orthographic projection of the first structural layer 510 on the base substrate 10 is within the orthographic projection of the second structural layer 520 on the base substrate 10, which indicates that the sectional area of the second barrier structure 50 on the plane parallel to the base substrate 10 is gradually varied, and gradually decreased along a direction away from the base substrate 10, in other words, the second barrier structure 50 is narrow at the top and wide at the bottom along the thickness direction of the base substrate 10, so that the structural stability of the second barrier structure 50 can be improved and the edge of the second barrier structure 50 is less likely to be broken. Similarly, the first barrier structure 20 may have a structure similar to the second barrier structure 50. Specifically, the first barrier structure 20 may include a third structural layer and a fourth structural layer parallel to the base substrate 10. The third structural layer is located at any position of the fourth structural layer away from the base substrate 10. An orthographic projection of the third structural layer on the base substrate 10 is within an orthographic projection of the fourth structural layer on the base substrate 10, that is, the first barrier structure 20 is narrow at the top and wide at the bottom, so that the edge of the first barrier structure 20 is less likely to be broken. In a specific embodiment, a cross section of the second barrier structure 50 on the plane perpendicular to the base substrate 10 and a cross section of the first barrier structure 20 on the plane of the base substrate 10 may be trapezoidal. Certainly, in other embodiments, cross-sectional structures of the first barrier structure 20 and the second barrier structure 50 in the thickness direction of the base substrate 10 may also be rectangular, inverted trapezoidal, etc.

As shown in FIG. 4, in an exemplary embodiment, the first structural layer 510 only has a first intersection point with a first tangent plane perpendicular to the base substrate 10, and the second structural layer 520 only has a second intersection point with a second tangent plane perpendicular to the base substrate 10. The first tangent plane is parallel to the second tangent plane, and both the first tangent plane and the second tangent plane are located on the same side of a center of the orthographic projection of the first structural layer 510 on the base substrate 10. A line segment connecting the first intersection point and the second intersection point forms a first angle α with the base substrate, and the first angle α is less than 60° and greater than 20°. The first tangent plane and the first structural layer 510 only have the first intersection point, which indicates that the first tangent plane is tangent to the first structural layer 510, and the first intersection point is a tangent point between the first tangent plane and the first structural layer 510. Similarly, the second tangent plane is tangent to the second structural layer 520, and the second intersection point is a tangent point between the second tangent plane and the second structural layer 520. The first angle α between the line segment for connecting the first intersection point and the second intersection point and the base substrate 10 is an angle between an outer wall of the second barrier structure 50 and the base substrate 10, that is, a slope of the outer wall of the second barrier structure 50. The first angle α being greater than or equal to 20 degrees and less than or equal to 60 degrees can ensure that the slope of the second barrier structure 50 is gentle, so that the auxiliary electrode and the second electrode on the second barrier structure 50 are less likely to be broken.

As shown in FIG. 3, in an exemplary embodiment, the display substrate may further include a plurality of auxiliary electrodes 501. The plurality of auxiliary electrodes 501 are arranged corresponding to a plurality of second barrier structures 50, and the auxiliary electrodes 501 may cover the corresponding second barrier structures 50. The auxiliary electrode 501 is arranged on the second barrier structure 50 and may be connected with the second electrode in the sub-pixel, on the one hand, the impedance of the second electrode layer can be reduced; on the other hand, the auxiliary electrode 501 can further reduce the slope of the second barrier structure 50. This is beneficial to vapor deposition to form the second electrode of the sub-pixel in a process of forming the display sub-pixel. In an exemplary embodiment, the thickness of the auxiliary electrode 501 is in a range of 3000 Å-5000 Å, for example, 3000 Å, 3500 Å, 4000 Å, 4500 Å, 5000 Å, etc.

FIG. 5 is a schematic structural view of a display panel according to an embodiment of this disclosure. As shown in FIG. 5, the display panel may include the display substrate as described in any embodiments of this disclosure, a light-emitting layer EML and a second electrode layer. The light-emitting layer EML may include a plurality of light-emitting structures. The plurality of light-emitting structures are in one-to-one correspondence with a plurality of first electrodes 30, and cover the corresponding first electrodes 30. The second electrode layer covers the light-emitting layer EML and a plurality of first barrier structures 20. A portion of the second electrode layer located within the second barrier structure 50 extends to the second barrier structure 50 and is connected with the auxiliary electrode 501. For example, the light-emitting layer EML may be an organic electroluminescent layer, the first electrode 30 may be an anode, the second electrode 70 may be a cathode, and the auxiliary electrode 501 may be an auxiliary cathode. The auxiliary cathode connects the cathodes into a whole to form a cathode layer. By applying a certain voltage between the cathode layer and the anode layer, a certain driving current is provided for the light-emitting layer EML to drive it to emit light. The auxiliary cathode covers the second barrier structure 50, on the one hand, the impedance of the cathode layer can be reduced; on the other hand, the auxiliary cathode can further reduce the slope of the second barrier structure 50, thus preventing the cathode formed in an evaporation process from being broken. In this exemplary embodiment, the material of the anode layer may include a transparent conductive material or a translucent conductive material, such as ITO, Ag, NiO, Al or graphene. The material of the cathode layer may include a metal or a combination of metals, for example, one of Al, Mg, Ca, Ba, Na, Li, K and Ag or any combination thereof.

As shown in FIG. 5, in an exemplary embodiment, the display panel may further include a first organic layer and a second organic layer. The first organic layer is located between the first electrode layer and the light-emitting layer EML. The first organic layer includes first organic structures in one-to-one correspondence with a plurality of first electrodes 30, and the first organic structures cover the corresponding first electrodes 30. The second organic layer is located between the light-emitting layer EML and the second electrode layer. The second organic layer includes second organic structures in one-to-one correspondence with the first electrodes 30, and the second organic structures cover the corresponding light-emitting structures. At least one of the light-emitting layer EML, the first organic layer and the second organic layer is formed by an inkjet process. The first organic layer is located between the organic electroluminescent layer and the base substrate, and the second organic layer is located on a side of the organic electroluminescent layer away from the base substrate. The first organic layer may include a hole injection layer HIL and a hole transport layer HTL. The second organic layer may include an electron transport layer ETL and an electron injection layer EIL. The specific structures of the hole injection layer HIL, the hole transport layer HTL, the electron transport layer ETL and the electron injection layer EIL will not be detailed here. Adjacent light-emitting functional layers may share one or more of the hole injection layer HIL, the hole transport layer HTL, the electron transport layer ETL and the electron injection layer EIL.

This disclosure further provides a preparation method for a display substrate as described in any of the above embodiments, and the preparation method may include the following steps.

S110, a base substrate 10 is provided.

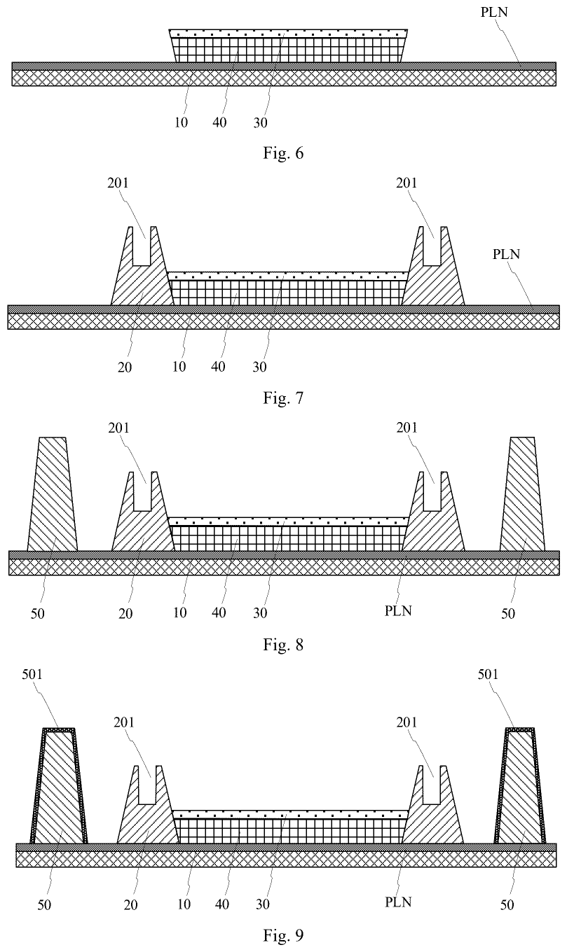

S120, a first electrode layer is formed on a side of the base substrate 10, and the first electrode layer includes a plurality of first electrodes 30. As shown in FIG. 6, a planarization layer is formed on the base substrate 10; and then a cushion layer 40 is formed on the planarization layer through gluing, exposure and development processes; a first electrode layer is formed on the cushion layer 40 by a sputtering process, and then the first electrodes 30 that are discrete are formed by a patterning process. The structure related to the first electrode layer may be described in the above embodiment, and will not be detailed here.

S130, a plurality of first barrier structures 20 are formed on the base substrate 10. The plurality of first barrier structures 20 in one-to-one correspondence with the first electrodes 30, and the first electrodes 30 are within a first region enclosed by the first barrier structures 20; the first barrier structures 20 have a first height h1 in the thickness direction of the base substrate 30; the first electrodes 30 have a second height h2 in the thickness direction of the base substrate 30; the first height hl is greater than the second height h2; and a separation groove 201 is provided on a side surface of each of the first barrier structures 20 away from the base substrate 30. As shown in FIG. 7, a plurality of first barrier structures 20 may be formed on the base substrate 10 by a gluing display process, and the orthographic projection of the first barrier structures 20 on the base substrate 10 may be circular, rectangular, oval, etc. In a specific embodiment, the orthographic projection of the first barrier structure 20 on the base substrate 10 is circular, which can reduce the process difficulty.

The height of the first barrier structure 20 is greater than that of the first electrode 30, so that functional film layers of the display sub-pixel may be formed on the first electrode 30 and within the first region formed by the first barrier structure 20.

As described in the above embodiments, various film layers of the display sub-pixels of this disclosure may be formed through an inkjet printing process. A separation groove 201 may be formed on a surface of a side of the first barrier structure 20 away from the base substrate 10. An edge of the ink ejected by the printing device may be trimmed by the separation groove 201, to allow the effective ink on the first electrode 30 to be separated from the excessive ink overflowing from the first barrier structure 20, so that the morphology of the dried ink can be effectively controlled, effectively controlling the thickness of the film layer of the display sub-pixels uniformly distributed while the ultra-high ppi display panel is manufactured by the solution method, and solving the problem that the morphology of the ink after being solidified is difficult to control in the related art. The specific structures of the separation groove 201 and the first barrier structure 20 have been described in the above embodiments, and will not be detailed here.

In an exemplary embodiment, the preparation method may further include:

S140, a plurality of second barrier structures 50 are formed on the base substrate 10. As shown in FIG. 8, the plurality of second barrier structures 50 are arranged in one-to-one correspondence with the plurality of first barrier structures 20. The first barrier structure 20 is located in a second region enclosed by the corresponding second barrier structure 50. There is a gap 60 between the first barrier structure 20 and the corresponding second barrier structure 50. The second barrier structure 50 have a third height h3 in the thickness direction of the base substrate 10, and the third height h3 is greater than the first height h1.

For example, second barrier structures 50 in one-to-one correspondence with the first barrier structures 20 may be formed on the base substrate 10 by gluing and developing processes. The second barrier structures 50 circumferentially surround the first barrier structures 20 provided therein, so that the second barrier structures can isolate the display sub-pixels located therein from the adjacent display sub-pixels. There is a gap 60 between the second barrier structure 50 and the first barrier structure 20 located therein to form a trench. In the inkjet process, ink overflowing from the first barrier structure 20 flows into the trench and is blocked by the second barrier structure 50 to avoid crosstalk with other sub-pixels.

S150, an auxiliary electrode 501 is formed on the second barrier structure 50.

As shown in FIG. 9, the auxiliary electrode layer may be formed on the second barrier structure 50 by a sputtering process, and then patterned by an exposure display, so that auxiliary electrodes 501 covering the second barrier structure 50 can be obtained.

The specific structures of the second barrier structure 50, the trench and the auxiliary electrode 501 have been described in the above embodiments, and will not be detailed here.

Other embodiments of this disclosure will be apparent to those skilled in the art under consideration of the specification and practices disclosed herein. This disclosure is intended to cover any variations, uses, or adaptations that follow general principles of this disclosure and include the common knowledge or customary means in the art undisclosed in this disclosure. The specification and embodiments are only considered exemplary, and the real scope and spirit of this disclosure are indicated by the appended claims.

1. A display substrate, comprising:
a base substrate;
a plurality of first barrier structures arranged in an array on a side of the base substrate, each of the first barrier structures enclosing a first region; and
a first electrode layer comprising a plurality of first electrodes, the plurality of first electrodes being arranged corresponding to the plurality of first barrier structures, and each of the first electrodes being within the first region enclosed by the corresponding first barrier structure,
wherein each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate.

2. The display substrate according to claim 1, wherein a ratio of a recessing depth of the separation groove in the thickness direction of the base substrate to the first height is greater than or equal to 0.2 and less than or equal to 0.4.

3. The display substrate according to claim 1, wherein an orthographic projection of the side surface of each of the first barrier structures, on which the separation groove is formed, on the base substrate has a first width; an orthographic projection of an opening of the separation groove on the base substrate has a second width;
and a ratio of the second width to the first width is greater than or equal to 0.2 and less than or equal to 0.6.

4. The display substrate according to claim 1, wherein the ratio of the second height to the first height is greater than or equal to 0.4 and less than or equal to 0.7.

5. The display substrate according to claim 1, further comprising:
a plurality of second barrier structures arranged in an array on the base substrate and corresponding to the plurality of first barrier structures, each of the second barrier structures enclosing a second region,
wherein each of the first barrier structures is within the second region enclosed by the corresponding second barrier structure, and there is a gap between the first barrier structure and the corresponding second barrier structure;
each of the second barrier structures has a third height in the thickness direction of the base substrate, and the third height is greater than the first height.

6. The display substrate according to claim 5, wherein a ratio of the first height to the third height is greater than or equal to 0.4 and less than or equal to 0.8.

7. The display substrate according to claim 5, wherein a distance between centers of orthographic projections of any adjacent two of the second barrier structures on the base substrate is D;
an orthographic projection of each of the first barrier structures on the base substrate has a first side edge and a second side edge opposite to each other; any normal line of the first side edge intersects with the first side edge at a first node and intersects with the second side edge at a second node; and a distance between the first node and the second node is d1;
an orthographic projection of each of the second barrier structures on the base substrate has a third side edge and a fourth side edge opposite to each other; any normal line of the third side edge intersects with the third side edge at a third node and intersects with the fourth side edge at a fourth node; and a distance between the third node and the fourth node is d2;
wherein dl/D is 0.1-0.3 and d2/D is 0.1-0.3.

8. The display substrate according to claim 5, wherein the second side edge is on a side of the first side edge away from an orthographic projection of the corresponding first electrode on the base substrate, and the fourth side edge is on a side of the third side edge away from an orthographic projection of the corresponding first electrode on the base substrate;
any normal line of the second side edge intersects with the second side edge at a fifth node and intersects with the third side edge at a sixth node, and a distance between the fifth node and the sixth node is d3;
wherein d3/D is 0.08-0.20.

9. The display substrate according to claim 5, wherein the second barrier structure comprises a first structural layer and a second structural layer parallel to the base substrate, the first structural layer is located at any position on a side of the second structural layer away from the base substrate, and an orthographic projection of the first structural layer on the base substrate is within an orthographic projection of the second structural layer on the base substrate;
the first barrier structure comprises a third structural layer and a fourth structural layer parallel to the base substrate, the third structural layer is located at any position of the fourth structural layer away from the base substrate, and an orthographic projection of the third structural layer on the base substrate is within an orthographic projection of the fourth structural layer on the base substrate.

10. The display substrate according to claim 9, wherein the first structural layer only has a first intersection point with a first tangent plane perpendicular to the base substrate; the second structural layer only has a second intersection point with a second tangent plane perpendicular to the base substrate; the first tangent plane is parallel to the second tangent plane, and the first tangent plane and the second tangent plane are located on a same side of a center of the orthographic projection of the first structural layer on the base substrate; a line segment connecting the first intersection point and the second intersection point forms a first angle with the base substrate, and the first angle is greater than or equal to 20° and less than or equal to 60°.

11. The display substrate according to claim 5, further comprising:
a plurality of auxiliary electrodes arranged corresponding to the plurality of second barrier structures, wherein the auxiliary electrodes correspondingly cover the second barrier structures.

12. The display substrate according to claim 11, wherein a thickness of each of the auxiliary electrodes is 3000 Å to 5000 Å.

13. The display substrate according to claim 5, wherein the second barrier structures are made of a resin material, and the resin material has a viscosity of 20 cps to 40 cps.

14. The display substrate according to claim 5, wherein a distance between centers of orthographic projections of any adjacent two of the second barrier structures on the base substrate is less than or equal to 10 μm.

15. The display substrate according to claim 1, further comprising:
a plurality of cushion layers arranged corresponding to the plurality of first electrodes, and positioned between the first electrodes and the base substrate,
wherein each first barrier structure and each first electrode are located on a surface of a side of the corresponding cushion layer away from the base substrate, and the first height and the second height each comprise a thickness of the corresponding cushion layer in the thickness direction of the base substrate; or
each of the cushion layers is located within the first region formed by the corresponding first barrier structure, the second height comprises the thickness of the corresponding cushion layer in the thickness direction of the base substrate, and the first height does not comprise the thickness of the corresponding cushion layer in the thickness direction of the base substrate.

16. A display panel, comprising:
a display substrate, comprising: a base substrate; a plurality of first barrier structures arranged in an array on a side of the base substrate, each of the first barrier structures enclosing a first region; and a first electrode layer comprising a plurality of first electrodes, the plurality of first electrodes being arranged corresponding to the plurality of first barrier structures, and each of the first electrodes being within the first region enclosed by the corresponding first barrier structure, wherein each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate;
a light-emitting layer comprising a plurality of light-emitting structures, wherein the plurality of light-emitting structures are in one-to-one correspondence with the plurality of first electrodes, and the light-emitting structures correspondingly cover the first electrodes; and
a second electrode layer covering the light-emitting layer and the plurality of first barrier structures, wherein a portion of the second electrode layer within the second barrier structure extends to the second barrier structure and is connected with the auxiliary electrode.

17. The display panel according to claim 16, further comprising:
a first organic layer between the first electrode layer and the light-emitting layer, wherein the first organic layer further comprises first organic structures in one-to-one correspondence with the plurality of first electrodes, and the first organic structures correspondingly cover the first electrodes; and
a second organic layer between the light-emitting layer and the second electrode layer, wherein the second organic layer comprises second organic structures in one-to-one correspondence with the plurality of first electrodes, and the second organic structures correspondingly cover the light-emitting structures,
wherein at least one of the light-emitting layer, the first organic layer, and the second organic layer is formed by an inkjet process.

18. A preparation method for a display substrate, wherein the display substrate comprises: a base substrate; a plurality of first barrier structures arranged in an array, each of the first barrier structures enclosing a first region; and a first electrode layer,
wherein the preparation method comprises:
providing the base substrate;
forming the first electrode layer on a side of the base substrate, wherein the first electrode layer comprises a plurality of first electrodes; and
forming the plurality of first barrier structures on the base substrate, wherein the plurality of first barrier structures are in one-to-one correspondence with the plurality of first electrodes, and each of the first electrodes is within the first region enclosed by the corresponding first barrier structure; each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate.

19. A preparation method for the display substrate according to claim 5, comprising:
providing a base substrate;
forming a first electrode layer on a side of the base substrate, wherein the first electrode layer comprises a plurality of first electrodes;
forming a plurality of first barrier structures on the base substrate, wherein the plurality of first barrier structures are in one-to-one correspondence with the plurality of first electrodes, and each of the first electrodes is within a first region enclosed by the corresponding first barrier structure; each of the first barrier structures has a first height in a thickness direction of the base substrate, each of the first electrodes has a second height in the thickness direction of the base substrate, the first height is greater than the second height, and a separation groove is provided on a side surface of each of the first barrier structures away from the base substrate; and
forming a plurality of second barrier structures on the base substrate, wherein the plurality of second barrier structures are arranged in one-to-one correspondence with the plurality of first barrier structures; each of the first barrier structures is within a second region enclosed by the corresponding second barrier structure; there is a gap between the first barrier structure and the corresponding second barrier structure; and each of the second barrier structures has a third height in the thickness direction of the base substrate, and the third height is greater than the first height.

20. The preparation method according to claim 19, wherein a distance between centers of orthographic projections of any adjacent two of the second barrier structures on the base substrate is D;
an orthographic projection of each of the first barrier structures on the base substrate has a first side edge and a second side edge opposite to each other; any normal line of the first side edge intersects with the first side edge at a first node and intersects with the second side edge at a second node; and a distance between the first node and the second node is d1;
an orthographic projection of each of the second barrier structures on the base substrate has a third side edge and a fourth side edge opposite to each other; any normal line of the third side edge intersects with the third side edge at a third node and intersects with the fourth side edge at a fourth node; and a distance between the third node and the fourth node is d2;
wherein d1/D is 0.1-0.3 and d2/D is 0.1-0.3.
